(19) United States
(12) Patent Application Publication
(10) Pub. No.: US 2004/0198024 A1
(43) Pub. Date: Oct. 7, 2004

(54) Method for cutting semiconductor wafer using laser scribing process

(75) Inventors: Jeong Goo Yoon, Kyungki-do (KR); Bang Won Oh, Kyungki-do (KR); Ju Hyun Kim, Kyungki-do (KR); Byung Deuk Moon, Kyungki-do (KR); Kuk Hwea Yi, Seoul (KR)

Correspondence Address: LOWE HAUPTMAN GOPSTEIN GILMAN & BERNER, LLP, Suite 310, 1700 Diagonal Road, Alexandria, VA, 22314, US

(73) Assignee: Samsung Electro-Mechanics Co., Ltd.

(21) Appl. No.: 10/462,782

(22) Filed: Jun. 17, 2003

(30) Foreign Application Priority Data
Apr. 7, 2003 (KR) 2003-21703

(51) Int. Cl. H01L 21/301

(52) U.S. Cl. 438/463

(57) ABSTRACT

Disclosed herein is a method for cutting a semiconductor wafer having a semiconductor layer formed on the top surface thereof by units of a chip having a prescribed size. The method comprises the steps of lapping the bottom surface of the wafer so that the wafer has a prescribed thickness, and scanning a laser beam onto the bottom surface of the wafer to form a scribe line on the bottom surface of the wafer. The chip is defined by the scribe line. The method further comprises polishing the bottom surface of the wafer having the scribe line formed thereon, and dividing the wafer into a plurality of the chips along the scribe line. With the method of the present invention, contaminants, such as dust or spots, produced in the course of forming the scribe line is easily removed without an additional cleaning process. Furthermore, a semiconductor wafer having high hardness, such as a GaN-based semiconductor wafer, is easily cut by the combination of the lapping step for reducing the thickness of the wafer and the scribing step carried out using the laser beam.

### BACKGROUND OF THE INVENTION

1. Field of the Invention

The present invention relates to a method for cutting a semiconductor wafer, and more particularly to a method for cutting a semiconductor wafer that is capable of removing contaminants produced when a laser scribing process is carried out on the semiconductor wafer.

2. Description of the Related Art

As well known to those skilled in the art, a conventional method for cutting a wafer having a semiconductor layer formed thereon by units of a chip uses a dicing saw with diamond tips or a scriber. The dicing saw is a cutting device comprising a disc-shaped blade with diamond tips, which is rotated for cutting out the wafer or forming on the wafer a groove with a wide width corresponding to a width of the blade. On the other hand, the scriber is a device for forming a scribe line having a very narrow width and a prescribed depth on the wafer by means of a reciprocating linear movement of the tip of the scriber, to which a diamond tip is attached. The conventional method for cutting the wafer using the dicing saw has a disadvantage in that chipping or cracking may occur on the cut surface of the wafer, and thus a precise cutting process is not ensured. For this reason, the method for cutting the wafer using the scriber is widely used as a cutting process for manufacturing a semiconductor chip.

However, the method for cutting the wafer using the scriber also uses a mechanical movement of the diamond tip. As a result, a great quantity of contaminants is produced in the course of cutting the wafer. In addition, undesired exfoliation of the semiconductor layer may occur due to the mechanical force from the scriber.

The above problems seriously affect a semiconductor wafer cutting process for manufacturing a blue light emitting diode. A semiconductor layer of the blue light emitting diode is generally made of a GaN-based compound semiconductor material, such as GaN, InGaN, GaAlN, etc. To grow crystal of such a semiconductor material, a sapphire substrate is mainly used as the wafer. The crystal of the sapphire substrate is considerably different from that of the GaN-based compound semiconductor layer. Consequently, the GaN-based compound semiconductor layer easily peels off the sapphire substrate. Furthermore, the sapphire substrate and the GaN-based compound semiconductor layer each have a Mohs hardness of approximately 9, which indicates a very high hardness. On this account, it takes much time to cut the semiconductor wafer even though a scriber with a diamond tip is used. The time required in such a cutting process generally accounts for approximately 70% of the time required for the whole manufacturing processes.

To solve the aforesaid problems, a conventional method for cutting a GaN-based semiconductor wafer has been proposed, which is disclosed in Japanese Unexamined Patent Publication No. H5-315646. The conventional method uses a dicer and scriber to cut the solid GaN-based semiconductor wafer.

FIG. 1 is a cross sectional view of a GaN-based compound semiconductor wafer which is cut according to a conventional method for cutting a semiconductor wafer. As shown in FIG. 1, a sapphire wafer 1 has a GaN-based compound semiconductor layer 3 formed on the top surface thereof. A groove 4 is formed through a GaN-based compound semiconductor layer 3 to the top surface of a sapphire wafer 1 using a dicer (not shown), and then a scribe line 5 is formed on the top surface of the sapphire 1 having the groove 4 formed thereon. Consequently, a semiconductor wafer processed as shown in FIG. 1 is obtained.

According to the conventional method, the groove 5 is preliminarily formed using the dicer to reduce the cutting time, and the semiconductor wafer is divided into a plurality of chips using the scribe line without damaging the crystal of the semiconductor layer 3.

Although the sapphire substrate or the GaN-based compound semiconductor layer is cut using the aforesaid conventional method, however, it still takes much time to cut the semiconductor wafer since the sapphire substrate or the GaN-based compound semiconductor layer is strong and solid. Moreover, the crystal of the semiconductor layer may be damaged since the semiconductor wafer is cut by machining.

In recent years, a scribing process using a laser beam has been proposed to solve the aforesaid problems. In case of using the laser beam, a scribe line can be easily formed on the semiconductor wafer so that the processing time is effectively reduced and damage to the crystal of the semiconductor layer is decreased. When the scribe line is formed using the laser beam, however, a larger amount of dust is produced. The dust contaminates the semiconductor layer, which will constitute a device at a following process, as shown in FIG. 2.

The contamination of the semiconductor layer caused in the course of forming the scribe line may deteriorate the luminance characteristic of the diode, especially in case of the light emitting diode made of the above-stated GaN-based compound semiconductor.

Consequently, a cleaning process for preventing the contamination of the semiconductor layer is inevitably added, which increases steps of a cutting process even when it is carried out using the laser beam. In addition, efficiency of the process is decreased.

### SUMMARY OF THE INVENTION

Therefore, the present invention has been made in view of the above problems, and it is an object of the present invention to provide a method for cutting a semiconductor wafer that is capable of quickly cutting a sapphire wafer having a GaN-based compound semiconductor layer of high hardness formed thereon using a laser beam and easily removing contaminants, such as dust or spots, produced in the course of cutting the semiconductor wafer.

In accordance with the present invention, the above and other objects can be accomplished by the provision of a method for cutting a semiconductor wafer having a semiconductor layer formed on the top surface thereof by units of a chip having a prescribed size, comprising the steps of: lapping the bottom surface of the wafer so that the wafer has a prescribed thickness; scanning a laser beam onto the bottom surface of the wafer to form a scribe line on the bottom surface of the wafer, the chip being defined by the scribe line; polishing the bottom surface of the wafer having the scribe line formed thereon; and dividing the wafer into a plurality of the chips along the scribe line.

In a preferred embodiment, the polishing step comprises removing contaminants produced when the scribe line is formed on the bottom surface of the wafer. Preferably, the thickness of the wafer removed at the step of polishing the bottom surface of the wafer may be smaller than the depth of the scribe line.

Preferably, the semiconductor layer formed on the wafer may be a GaN-based compound semiconductor layer, and the wafer may be a sapphire wafer. Accordingly, the present invention has a large advantage in the case of cutting a semiconductor wafer having high hardness.

To promote the complete understanding of the present invention, an ordinary semiconductor wafer cutting process will now be described. Generally, the lapping and polishing steps are added to the semiconductor wafer cutting process to reduce the thickness of the wafer and reduce surface roughness of the bottom surface of the wafer.

The thickness of the wafer is greatly reduced by going through the lapping step. Consequently, the process of cutting the wafer using the scribe lines formed at the subsequent step is effectively carried out. The lapping step may be carried out using a diluted solution containing particles having hardness higher than that of the wafer, i.e., slurry to abrade the bottom surface of the wafer. The surface of the wafer obtained by the lapping step is coarser than the desired surface roughness.

Consequently, the polishing step may be subsequently carried out so that the bottom surface of the wafer obtained at the lapping step has the desired surface roughness.

The present invention is characterized in that a laser-scribing step is employed to improve efficiency of the process, and the sequence of the lapping and polishing steps carried out before the scribing step is appropriately controlled to effectively remove the contaminants produced at the scribing step.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross sectional view of a GaN-based compound semiconductor wafer which is cut according to a conventional method for cutting a semiconductor wafer;

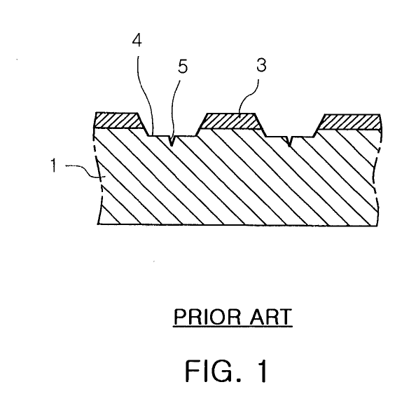

FIG. 2 is a photograph showing a surface state of a semiconductor wafer after an ordinary laser scribing process is carried out on the semiconductor wafer;

FIGS. 3a to 3e are cross sectional views respectively illustrating successive steps of a method for cutting a semiconductor wafer using a laser scribing process according to the present invention; and

FIG. 4 is a photograph showing a surface state of a semiconductor wafer after the method for cutting the semiconductor wafer according to the present invention is carried out on the semiconductor wafer.

### DESCRIPTION OF THE PREFERRED EMBODIMENTS

Now, preferred embodiments of the present invention will be described in detail with reference to the annexed drawings.

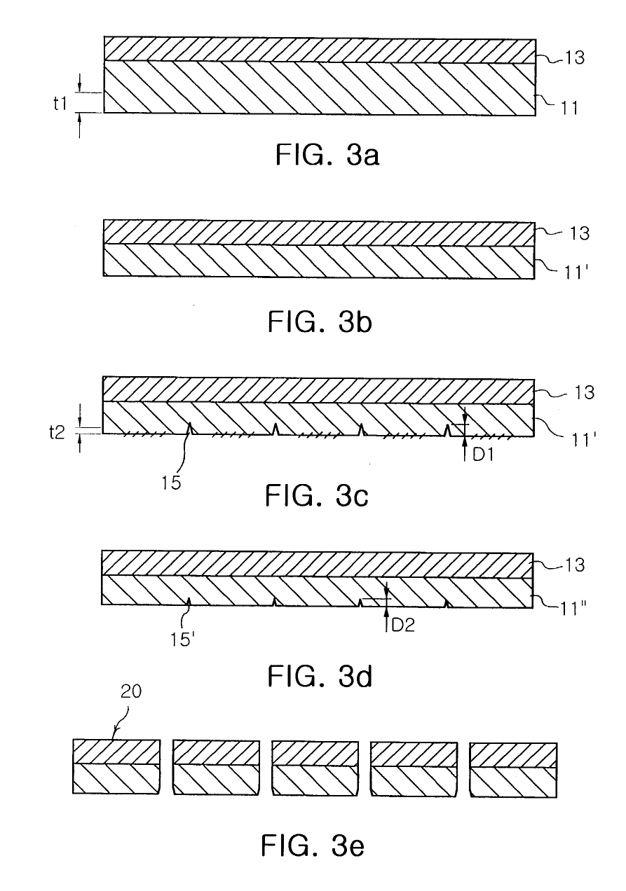

FIGS. 3a to 3e are cross sectional views respectively illustrating successive steps of a method for cutting a semiconductor wafer using a laser scribing process according to the present invention. Hereinafter, the sequence of cutting the semiconductor wafer will be described in detail with reference to FIGS. 3a to 3e.

First, a wafer 11 having a semiconductor layer 13 formed on the top surface thereof is prepared, as shown in FIG. 3a. The method for cutting the semiconductor wafer is very effective as compared to the conventional method for cutting the semiconductor wafer in cases where it is used to cut relatively strong and solid semiconductor layer and wafer, although the method for cutting the semiconductor wafer is not limited by the kinds of the semiconductor layer 13 and the wafer 11. For example, the method for cutting the semiconductor wafer according to the present invention is particularly used to cut the a GaN-based compound semiconductor wafer for a blue light emitting diode, i.e., a GaN-based compound semiconductor layer and a sapphire wafer.

Second, the bottom surface of the wafer 11 is lapped to remove a portion of the wafer having a thickness of t1 as indicated in FIG. 3a. Consequently, the thickness of the lapped wafer 11′ of FIG. 3b is reduced as compared to the thickness of the wafer 11 of FIG. 3a so that the semiconductor wafer is more easily cut. This lapping step may be carried out using a diluted solution containing particles of high hardness to abrade the bottom surface of the wafer. At the lapping step, the surface roughness of the bottom surface of the wafer may be reduced to some extent.

Third, a laser beam is scanned onto the bottom surface of the lapped wafer 11′ to form a scribe line 15, by which the semiconductor wafer is divided by units of a chip, as shown in FIG. 3c. The scribe line 15 is formed on the bottom surface of the lapped wafer 11′ in a lattice pattern, and defines the chip, which has a prescribed size. Also, the scribe line 15 is formed on the bottom surface of the lapped wafer 11′ with a fine width and a prescribed depth of D1. Consequently, the lapped wafer 11′ can be easily divided into a plurality of the chips when a constant external force is applied to the lapped wafer 11′ at the subsequent step.

The scribing process is carried out using a scriber having a diamond tip attached to the tip end thereof, which is linearly reciprocated, to form the scribe line in the conventional art. On the other hand, the scribing step is carried out using a laser beam to easily form the scribe line even on the wafer having high hardness, such as the sapphire substrate, in the present invention.

Fourth, the bottom surface of the lapped surface 11′ having the scribe line formed thereon is polished. FIG. 3d shows the polished wafer 11″, the bottom surface of which is polished. The polishing step further improves the surface roughness of the bottom surface of the polished wafer 11″, and a portion of the wafer having a thickness of t2 as indicated in FIG. 3c is removed at the polishing step. Preferably, the thickness t2 of the wafer removed at the polishing step is smaller than the depth D1 of the scribe line 15 formed at the scribing step as shown in FIG. 3c. Consequently, the scribe line 15′ having a depth of D2, which is decreased in proportion to the thickness of the lapped wafer 11′ removed at the polishing step, is left on the polished wafer 11″.

For example, it is preferable that the thickness t2 of the wafer removed at the polishing step is not more than 80 μm if the depth D1 of the scribe line is approximately 100 μm. The surface roughness of the bottom surface of the wafer is firstly reduced to some extent at the lapping step. Consequently, desired surface roughness is obtained even though the thickness of the wafer is reduced by approximately 80 μm at the polishing step, and the wafer is easily divided by units of a chip using an external force at the subsequent step even when the depth D2 of the scribe line is approximately 20 μm.

In the conventional art, the polishing step is successively carried out immediately after the lapping step, which is similar to the polishing step in terms of a processing condition. On the other hand, the scribe line is formed after the lapping step, and then the bottom surface of the wafer having the scribe line formed thereon is polished according to the present invention.

As described above, the scribing step is followed by the polishing step according to the present invention. Consequently, a large amount of dust produced at the laser scribing step and unwanted spots formed on the surface of the wafer due to the dust can be effectively removed without an additional cleaning step, as shown in FIG. 3c. In other words, the method for cutting the semiconductor wafer according to the present invention eliminates a cleaning step for removing contaminants, such as the dust produced at the scribing step and the spots formed due to the dust.

Finally, the semiconductor wafer obtained as shown in FIG. 3d is divided by units of a chip 20 along the scribe line 15′ by applying a constant external force to the semiconductor wafer, as shown in FIG. 3e. The step of dividing the semiconductor wafer into a plurality of the chip 20 along the scribe line 15′ may be carried out in such a manner that the semiconductor wafer is divided by units of a chip by means of a driving force when the semiconductor wafer passes between rollers.

As mentioned above, the method for cutting the semiconductor wafer according to the present invention eliminates the cleaning step for removing contaminants, such as the dust produced at the scribing step and the spots formed due to the dust. That is to say, the polishing step is carried out after the scribing step instead of successively performing the lapping and polishing steps, so that the contaminants produced at the scribing step are removed at the polishing step.

The method for cutting the semiconductor wafer according to the present invention is suitably used to manufacture a blue light emitting diode. Generally, a GaN-based compound semiconductor layer and a sapphire wafer used for growth of such a semiconductor layer each have a Mohs hardness of 9, which means that the GaN-based compound semiconductor layer and the sapphire wafer are very strong and solid. For this reason, chipping or cracking may occur on the cut surface of the wafer, or it takes much time to cut the semiconductor wafer.

In comparison with the aforesaid conventional art, the method for cutting the semiconductor wafer according to the present invention is characterized in that the thickness of the wafer is appropriately reduced at the lapping step, the scribe line is formed using the laser beam, and then the polishing step is carried out, thereby reducing the total processing time, eliminating an additional cleaning step for removing the contaminants produced at the scribing step, and obtaining the wafer whose surface is clean.

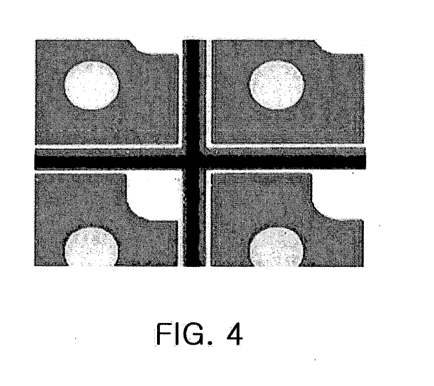

FIG. 4 is a photograph showing a surface state of a semiconductor wafer after the method for cutting the semiconductor wafer according to the present invention is carried out on the semiconductor wafer.

The semiconductor wafer as shown in FIG. 4 is a GaN-based compound semiconductor wafer, the surface of which is polished after the scribing step is carried out according to the method for cutting the semiconductor wafer of the present invention. It can be seen from the FIG. 4 that the surface of the wafer obtained according to the present invention is very clean without spots as compared to the surface of the wafer obtained according to the conventional art.

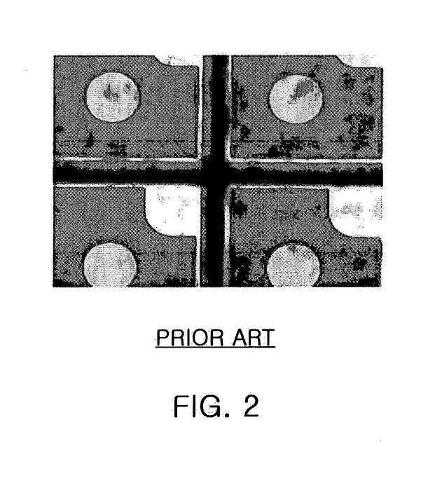

In case that the lapping and polishing steps are successively carried out before the scribing step, a large amount of dust is produced at the scribing step, and thus spots are formed on the surface of the wafer, as shown in FIG. 2. The contaminants, such as the dust and the spots, may have a bad influence upon the quality of the products. Especially, if the semiconductor wafer is used for a light emitting diode, luminescence brightness of the light emitting diode is decreased since spots are left on the surface of a finished chip.

The method for cutting the semiconductor wafer according to the present invention has an advantage in that contaminants, such as dust produced at the scribing step and spots formed due to the dust, is effectively removed by only the polishing step, without an additional step.

As apparent from the above description, the present invention provides a method for cutting a semiconductor wafer 15′ in which a laser scribing step is carried out after a lapping step is carried out and before a polishing step is carried out, thereby effectively removing contaminants, such as dust produced at the scribing step and spots formed due to the dust only going though the polishing step without an additional step. Furthermore, even a GaN-based compound semiconductor wafer having high hardness is effectively cut by the combination of the lapping step for reducing the thickness of the wafer and the scribing step carried out using a laser beam.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method of dividing a semiconductor wafer having a semiconductor layer formed on a top surface thereof to obtain at least a chip having a prescribed size, said method comprising the steps of:
lapping a bottom surface of the wafer until the wafer has a prescribed thickness;
scanning a laser beam onto the bottom surface of the wafer to form at least a scribe line on the bottom surface of the wafer, the chip being defined by the scribe line;
polishing the bottom surface of the wafer having the scribe line formed thereon, said polishing simultaneously removing contaminants produced during the formation of the scribe line on the bottom surface of the wafer; and
dividing the wafer along the scribe line to obtain the chip.

2. (canceled)

3. The method as set forth in claim 1, wherein the thickness of the wafer removed in the polishing step is smaller than the depth of the scribe line formed in the scanning step.

4. The method as set forth in claim 1, wherein the semiconductor layer formed on the wafer comprises a GaN-based compound semiconductor layer, and the wafer comprises a sapphire substrate.

5. The method as set forth in claim 1, wherein the steps are performed in the recited order.

6. The method as set forth in claim 5, wherein the thickness of the wafer removed in the polishing step is smaller than the thickness of the wafer removed in the lapping step.

7. The method as set forth in claim 1, wherein the polishing step is performed after the scanning step and comprises reducing the depth of the scribe line formed in the scanning step.

8. A method of dividing a wafer into a plurality of chips, said method comprising the steps of:
providing the wafer having opposite top and bottom surfaces, the wafer carrying a semiconductor layer on the top surface thereof;
lapping the bottom surface of the wafer until the wafer has a predetermined thickness;
forming a plurality of scribe lines on the bottom surface of the wafer, the chips being defined by the scribe lines;
after said forming, polishing the bottom surface of the wafer having the scribe lines formed thereon; and
dividing the wafer along the scribe lines to obtain the chips.

9. The method of claim 8, wherein said forming comprises scanning a laser beam onto the bottom surface of the wafer to create the scribe lines.

10. The method as set forth in claim 8, wherein the thickness of the wafer removed in the polishing step is smaller than the depth of the scribe lines formed in the forming step.

11. The method as set forth in claim 8, wherein the semiconductor layer formed on the wafer comprises a GaN-based compound semiconductor layer, and the wafer comprises a sapphire substrate.

12. The method as set forth in claim 8, wherein the steps are performed in the recited order.

13. The method as set forth in claim 10, wherein the thickness of the wafer removed in the polishing step is smaller than the thickness of the wafer removed in the lapping step.

14. The method as set forth in claim 10, wherein the polishing step comprises reducing the depth of the scribe line formed in the forming step.

15. A method of dividing a wafer having opposite top and bottom surfaces and carrying a semiconductor layer on the top surface thereof into a plurality of chips, said method consisting essentially of the steps of:
lapping the bottom surface of the wafer until the wafer has a predetermined thickness;
forming a plurality of scribe lines on the bottom surface of the wafer, the chips being defined by the scribe lines, said forming step simultaneously producing contaminants adhered to the bottom surface of the wafer;
polishing the bottom surface of the wafer to at least an extent sufficient to remove the contaminants without requiring an additional cleaning process; and
dividing the wafer along the scribe lines to obtain the chips.

16. The method as set forth in claim 15, wherein the steps are performed in the recited order.

17. The method of claim 16, wherein said forming comprises scanning a laser beam onto the bottom surface of the wafer to create the scribe lines.

18. The method as set forth in claim 17, wherein the thickness of the wafer removed in the polishing step is smaller than the depth of the scribe lines formed in the forming step.

19. The method as set forth in claim 18, wherein the polishing step comprises reducing the depth of the scribe line formed in the forming step.

20. The method as set forth in claim 19, wherein the thickness of the wafer removed in the polishing step is smaller than the thickness of the wafer removed in the lapping step.

21. The method as set forth in claim 20, wherein the semiconductor layer formed on the wafer comprises a GaN-based compound semiconductor layer, and the wafer comprises a sapphire substrate.
